(19) United States
(12) Patent Application Publication
(10) Pub. No.: US 2017/0240773 A1
(43) Pub. Date: Aug. 24, 2017

(54) METHOD OF ASSEMBLING NANOSCALE AND MICROSCALE OBJECTS IN TWO- AND THREE-DIMENSIONAL STRUCTURES

(71) Applicants: David J. CARTER, Concord, MA (US); THE CHARLES STARK DRAPER LABORATORY, INC., Cambridge, MA (US)

(72) Inventor: David J. Carter, Cambridge, MA (US)

(21) Appl. No.: 15/518,635

(22) PCT Filed: Nov. 10, 2015
(86) PCT No.: PCT/US2015/059912

§ 371 Date: Apr. 12, 2017

Related U.S. Application Data
(60) Provisional application No. 62/077,965, filed on Nov. 11, 2014.

(51) Int. Cl. C09J 7/00; B81C 1/00

(52) U.S. Cl. CPC C09J 7/00; B81C 1/00206; B81C 2201/0149

(57) ABSTRACT

A method of assembly of micro-scale objects includes forming a pattern of a first functional moiety on a surface of a substrate, contacting the surface of the substrate with a first liquid suspension including first micro-scale feedstock elements functionalized with a second functional moiety, complimentary to the first functional moiety, on first portions of the first micro-scale feedstock elements and functionalized with a third functional moiety on second portions of the first micro-scale feedstock elements, aligning the first portions of the first micro-scale feedstock elements with the surface of the substrate, and facilitating bonding the second functional moieties to the first functional moieties to form a first microstructure pattern of the first micro-scale feedstock elements on the surface of the substrate.

### CROSS-REFERENCE TO RELATED APPLICATION

This application claims priority under 35 U.S.C. §119(e) to U.S. Provisional Application Ser. No. 62/077,965 titled “METHOD OF ASSEMBLING NANOSCALE AND MICROSCALE OBJECT IN TWO- AND THREE-DIMENSIONAL STRUCTURES AND A SYNTHETIC GECKO ADHESIVE STRUCTURE MADE USING THE METHOD,” filed Nov. 11, 2014, which is incorporated herein by reference in its entirety for all purposes.

### BACKGROUND

One goal of modern materials science involves the production of macro-scale structures from micro-scale elements having dimensions on the order of microns or nanometers. Such structures may be tailored to have novel mechanical, electrical, and optical properties that are unobtainable using conventional manufacturing techniques. Conventional micro-scale manufacturing processes, for example, as used in the semiconductor industry are incapable of producing macro-scale structures from micro-scale elements. For example, conventional semiconductor manufacturing equipment and processes are incapable of producing micro-scale elements having aspect ratios much greater than about 50:1 or about 100:1. Conventional additive manufacturing equipment and processes (often referred to as “3-D printing”) are incapable of producing objects having dimensions on the order of microns or nanometers and are incapable of quickly producing macro-scale structures from micro-scale elements.

### SUMMARY

In accordance with one aspect, there is provided a method of assembly of micro-scale objects. The method comprises forming a pattern of a first functional moiety on a surface of a substrate, contacting the surface of the substrate with a first liquid suspension including first micro-scale feedstock elements functionalized with a second functional moiety, complimentary to the first functional moiety, on first portions of the first micro-scale feedstock elements, aligning the first portions of the first micro-scale feedstock elements in the first liquid suspension with the surface of the substrate, and facilitating bonding the second functional moieties to the first functional moieties to form a first microstructure pattern of the first micro-scale feedstock elements on the surface of the substrate.

In some embodiments, second portions of the first micro-scale feedstock elements are functionalized with a third functional moiety, and the method further comprises contacting the first microstructure pattern of the first micro-scale feedstock elements on the surface of the substrate with a second liquid suspension including second micro-scale feedstock elements functionalized with a fourth functional moiety, complimentary to the third functional moiety, on first portions of the second micro-scale feedstock elements, aligning the first portions of the second micro-scale feedstock elements in the second liquid suspension with the second portions of the first micro-scale feedstock elements, and facilitating bonding the fourth functional moieties to the third functional moieties to form the assembly of micro-scale objects on the surface of the substrate.

In some embodiments, the third functional moiety is the same as the first (or second) functional moiety. In some embodiments, the fourth functional moiety is the same as the second (or first) functional moiety.

In some embodiments, facilitating bonding the second functional moieties to the first functional moieties includes initiating bonding between the second functional moieties and the first functional moieties by one of application of thermal energy to the second functional moieties and/or the first functional moieties, application of radiation to the second functional moieties and/or the first functional moieties, and exposing the second functional moieties and/or the first functional moieties to a chemical catalyst.

In some embodiments, the method further comprises bonding the first functional moiety with a linker molecule to a metal adhesion element bonded to the surface of the substrate to form the pattern of the first functional moiety on the surface of the substrate.

In some embodiments, the method further comprises bonding the second functional moiety with a linker molecule to a metal adhesion element bonded to the first portion of the first micro-scale feedstock element.

In some embodiments, the method further comprises facilitating bonding a plurality of the second micro-scale feedstock elements to each of the second portions of the first micro-scale feedstock elements.

In some embodiments, the method further comprises contacting the assembly of micro-scale objects with a third liquid suspension including third micro-scale feedstock elements, aligning and positioning first portions of the third micro-scale feedstock elements in the third liquid suspension with second portions of the second micro-scale feedstock elements, and facilitating bonding the first portions of the third micro-scale feedstock elements to the second portions of the second micro-scale feedstock elements with complimentary click chemical groups.

In some embodiments, aligning and positioning first portions of third micro-scale feedstock elements with second portions of the second micro-scale feedstock elements includes aligning and positioning first portions of third micro-scale feedstock elements with second portions of the second micro-scale feedstock elements with a dielectrophoretic field.

In some embodiments, the method further comprises contacting the assembly of micro-scale objects with a fourth liquid suspension including one or more of carbon nanotubes, nanorods, and nanoparticles, aligning and positioning first portions of the one or more of carbon nanotubes, nanorods, and nanoparticles in the fourth liquid suspension with second portions of the third micro-scale feedstock elements, and bonding the one or more of carbon nanotubes, nanorods, and nanoparticles to the second portions of the third micro-scale feedstock elements with complimentary click chemical groups.

In some embodiments, aligning and positioning the first portions of the one or more of carbon nanotubes, nanorods, and nanoparticles with the second portions of the third micro-scale feedstock elements includes aligning and positioning the first portions of the one or more of carbon nanotubes, nanorods, and nanoparticles with the second portions of the third micro-scale feedstock elements with a dielectrophoretic field.

In some embodiments, the method comprises concurrently bonding at least two of i) the first portions of the first micro-scale feedstock elements to the substrate, ii) the second portions of the first micro-scale feedstock elements to the first portions of the second micro-scale feedstock elements, iii) the first portions of the third micro-scale feedstock elements to the second portions of the second micro-scale feedstock elements, and iv) the one or more of carbon nanotubes, nanorods, and nanoparticles to the second portions of the third micro-scale feedstock elements.

In some embodiments, facilitating bonding the second functional moieties to the first functional moieties includes facilitating bonding a first click chemical group to a complimentary click chemical group.

In some embodiments, facilitating bonding the second functional moieties to the first functional moieties includes facilitating bonding a first DNA strand to a complimentary DNA strand.

In some embodiments, the method further comprises bonding the first micro-scale feedstock elements to the surface of the substrate with an additional bonding mechanism.

In some embodiments, the method further comprises forming one of an electrical and an optical pathway to the substrate through one of the first micro-scale feedstock elements, the second micro-scale feedstock elements, the third micro-scale feedstock elements, and the one or more of carbon nanotubes, nanorods, and nanoparticles.

In some embodiments, the method results in the formation of a synthetic gecko adhesive.

In accordance with another aspect, there is provided an assembly of micro-scale objects comprising a plurality of first micro-scale feedstock elements having first portions bonded to a surface of a substrate in a repeating pattern with click chemical bonds and a plurality of second micro-scale feedstock elements having first portions bonded to second portions of the plurality of first micro-scale feedstock elements.

In some embodiments, at least a portion of one of the first micro-scale feedstock elements and the second micro-scale feedstock elements have length:width aspect ratios of at least about 20:1.

In some embodiments, the assembly further comprises a plurality of the second micro-scale feedstock elements bonded to each first micro-scale feedstock element.

In some embodiments, the assembly further comprises a plurality of third micro-scale feedstock elements having first portions bonded to second portions of the plurality of second micro-scale feedstock elements with click chemical bonds.

In some embodiments, the assembly further comprises a plurality of the third micro-scale feedstock elements bonded to each second micro-scale feedstock element.

In some embodiments, the assembly further comprises a plurality of carbon nanotubes bonded to each of the third micro-scale feedstock elements.

In some embodiments, the first micro-scale feedstock elements have greater cross-sectional areas than each of the second micro-scale feedstock elements and the third micro-scale feedstock elements.

In some embodiments, the second micro-scale feedstock elements have greater cross-sectional areas than the third micro-scale feedstock elements

In some embodiments, the first micro-scale feedstock elements have cross-sectional areas of less than about 80 μm².

In some embodiments, the assembly is configured to adhere to a glass surface via van der Waals forces with an adhesion strength of at least about 0.09 N of force per mm2.

In some embodiments, the assembly comprises a synthetic gecko adhesive.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1A illustrates a substrate patterned with a first group of click chemical groups;

FIG. 1B illustrates a solution including a first plurality of micro-scale feedstock elements functionalized with click chemical groups complimentary to the click chemical groups patterned on the substrate and the substrate in contact with the solution;

FIG. 1C illustrates the first plurality of micro-scale feedstock elements being bonded to the substrate with the click chemical groups;

FIG. 1D illustrates a solution including a second plurality of micro-scale feedstock elements applied to the substrate with the bonded first plurality of micro-scale feedstock elements;

FIG. 1E illustrates the second plurality of micro-scale feedstock elements being bonded to the first plurality of micro-scale feedstock elements with click chemical groups;

FIG. 1F illustrates a structure formed from the substrate, first plurality of micro-scale feedstock elements, second plurality of micro-scale feedstock elements, and a third plurality of micro-scale feedstock elements bonded to the second plurality of micro-scale feedstock elements;

FIG. 2 is a flowchart of an embodiment of a method of forming the structure of FIG. 1F.

FIG. 3A illustrates a structure formed during performance of a method of forming a plurality of micro-scale feedstock elements;

FIG. 3B illustrates another structure formed during performance of the method of forming the plurality of micro-scale feedstock elements;

FIG. 3C illustrates another structure formed during performance of the method of forming the plurality of micro-scale feedstock elements;

FIG. 3D illustrates another structure formed during performance of the method of forming the plurality of micro-scale feedstock elements;

FIG. 3D′ illustrates another structure formed during performance of the method of forming the plurality of micro-scale feedstock elements;

FIG. 3E illustrates another structure formed during performance of the method of forming the plurality of micro-scale feedstock elements;

FIG. 3F illustrates another structure formed during performance of the method of forming the plurality of micro-scale feedstock elements;

FIG. 3G illustrates another structure formed during performance of the method of forming the plurality of micro-scale feedstock elements;

FIG. 3H illustrates another structure formed during performance of the method of forming the plurality of micro-scale feedstock elements;

FIG. 3I illustrates another structure formed during performance of the method of forming the plurality of micro-scale feedstock elements;

FIG. 4 is a flowchart of an embodiment of a method for forming a plurality of micro-scale feedstock elements;

FIG. 5A is an elevational view of a structure used to form a mold for forming a plurality of micro-scale feedstock elements;

FIG. 5A′ is a plan view of the structure of FIG. 5A;

FIG. 5B is an elevational view of another structure used to form a mold for forming a plurality of micro-scale feedstock elements;

FIG. 5B′ is a plan view of the structure of FIG. 5B;

FIG. 5C illustrates a structure formed during performance of a method of forming a plurality of micro-scale feedstock elements;

FIG. 5D illustrates another structure formed during performance of the method of forming the plurality of micro-scale feedstock elements;

FIG. 5E illustrates another structure formed during performance of the method of forming the plurality of micro-scale feedstock elements;

FIG. 5F illustrates another structure formed during performance of the method of forming the plurality of micro-scale feedstock elements;

FIG. 5G illustrates another structure formed during performance of the method of forming the plurality of micro-scale feedstock elements;

FIG. 5H illustrates another structure formed during performance of the method of forming the plurality of micro-scale feedstock elements;

FIG. 6 is a flowchart of an embodiment of a method for forming a plurality of micro-scale feedstock elements;

FIG. 7 illustrates a solution of DNA functionalized micro-scale feedstock elements in a solution in contact with a substrate functionalized with complimentary DNA; and

FIG. 8 is a schematic illustration of a synthetic gecko adhesion hair.

### DETAILED DESCRIPTION

Aspects and embodiments disclosed herein are not limited in application to the details of construction and the arrangement of components set forth in the following description or illustrated in the drawings. Aspects and embodiments disclosed herein are capable of being practiced or of being carried out in various ways. Also, the phraseology and terminology used herein is for the purpose of description and should not be regarded as limiting. The use of “including,” “comprising,” “having,” “containing,” “involving,” and variations thereof herein is meant to encompass the items listed thereafter and equivalents thereof as well as additional items.

Aspects and embodiments disclosed herein are generally directed to the formation of novel macro-scale structures from micro-scale elements having dimensions on the order of microns or nanometers. The disclosed macro-scale structures have mechanical, electrical, thermal, and/or optical properties that are unobtainable using conventional manufacturing techniques. Aspects and embodiments disclosed herein include the formation of macro-scale objects from micro-scale elements using a combination of directed fluidic assembly and “click” chemistry and/or DNA selective assembly techniques. Although the term “micro-scale elements” is used herein, it should be understood that the feedstock elements or other structures described herein are not limited to having dimensions of a micron or greater. The term “micro-scale elements” also encompasses feedstock elements or other structures having characteristic dimensions (length, width, etc.) smaller than one micron, for example, as small as less than about 1 nanometer.

### Directed Fluidic Assembly (DFA)

Directed Fluidic Assembly (DFA) is an assembly method that allows structures made by dissimilar methods to be assembled together. It can be combined with planar micro/nanofabrication, micro-machining, 3D printing, and other fabrication modalities. DFA provides for rapid placement of homogeneous or heterogeneous feedstock onto a substrate or to other feedstock elements with controlled position and orientation. An advantage of DFA lies in the ability to use optimal methods to fabricate individual micro/nano components and assemble them into a permanently-bonded functional mechanical, electrical, thermal, fluidic, and/or thermal system. In some implementations DFA assembly is rapid: a feedstock spacing of 5 μm over a 100 mm wafer with a 2-minute assembly time corresponds to rates of 2.5 million objects bonded per second. Smaller feedstocks will assemble at even higher rates.

Aspects and embodiments disclosed herein utilize a DFA technique for directed fluidic assembly of submicron- to tens-of-micron-scale objects (feedstock) into millimeter-scale or larger structures (macro-scale structures). In some embodiments, high-aspect-ratio micro/nanofabricated feedstock structures of the same or of different length scales are fabricated in the plane of a substrate, released, and then combined by DFA into multiscale structures that have high aspect ratios perpendicular to a substrate. In some embodiments, bonds to and between feedstock elements are permanent and provide for electrical conduction, thermal conduction, and/or optical transmission as required by the assembled system.

In some embodiments, DFA techniques for assembling micro-scale elements into larger composite structures include methods such as dielectrophoresis, electrophoresis, flow, convection, capillary forces, and magnetic fields, diffusion, or combinations thereof for orienting and positioning the micro-scale elements during fabrication. Many approaches have been used to assemble particles and other micro and nano building blocks onto conductive or insulating surfaces or structures. The control and speed of the assembly depends on many parameters, for example, particle size, concentration, charge, flow speed and direction, voltage, frequency, dielectric constant, etc. When using assembly mechanisms that depend on fluidic, capillary or other forces, the assembly forces, although controlled, can not be turned on and off (on demand) as in dielectrophoresis (DEP) or electrophoresis (EP) based assembly. Electrophoresis is a directed assembly method for fast assembly but it requires micro-scale elements to be oriented during a fabrication process to have a charge. DEP assembly forces depend only on the dielectric constant of the particle or the feedstock and therefore are more suitable for use to assemble uncharged feedstock. DEP assembly may be used to assemble nano and micro scale particles, and/or nanotube bundles into two and three-dimensional structures in seconds over a large area with precise alignment at desired locations. Based on the dilution of the feedstock solution and the strength of the applied electric field one can control the rate of assembly. Since the DEP force polarizes the feed stock, it leads to alignment of feedstock to orient the feedstock during assembly. Directionality of the nanomaterials as well as nanoscale feedstocks during assembly can effectively be controlled by controlling the applied electric field lines/gradients. The DEP assembly force can be effectively applied at the nano or microscale.

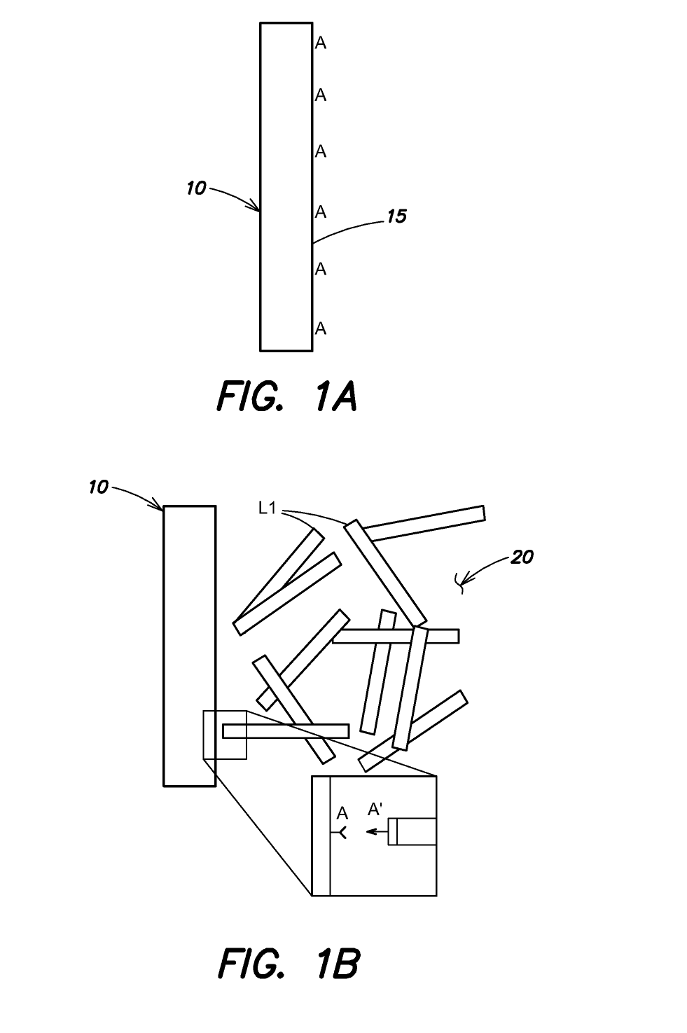

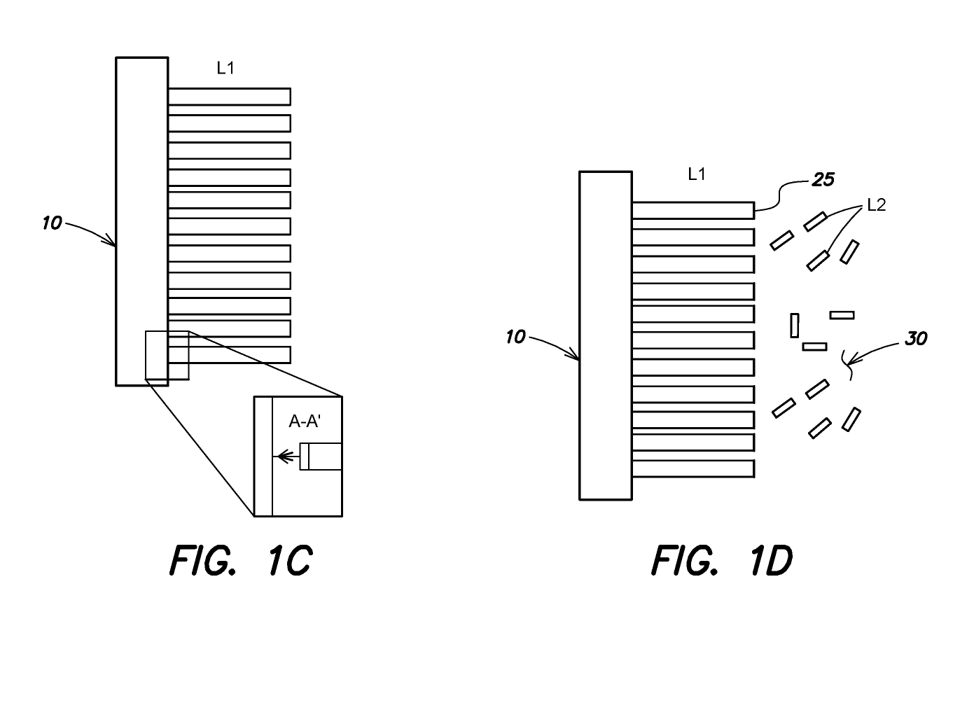

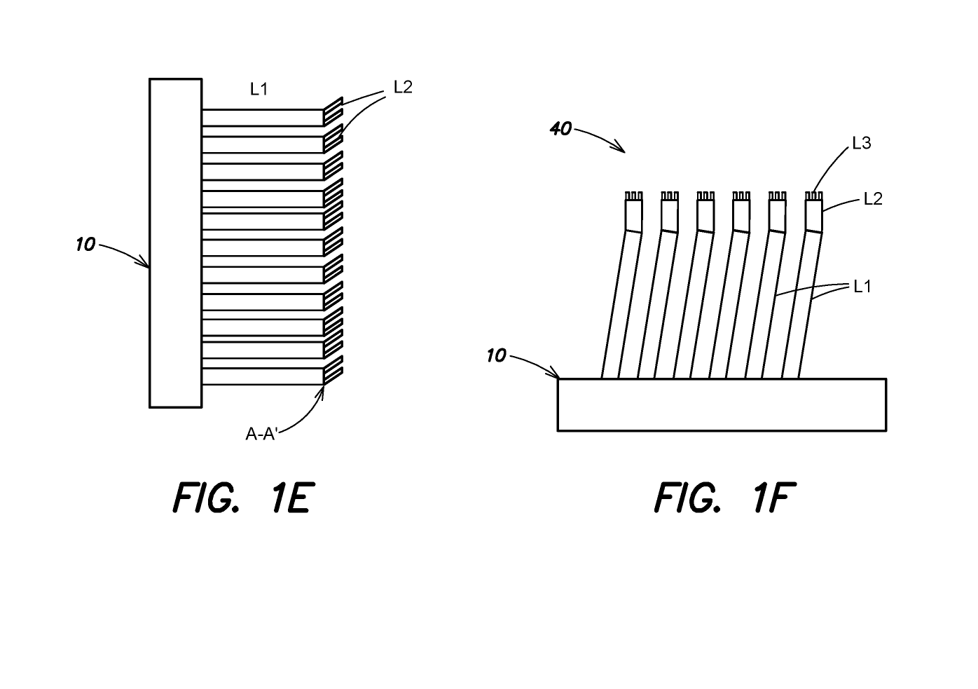

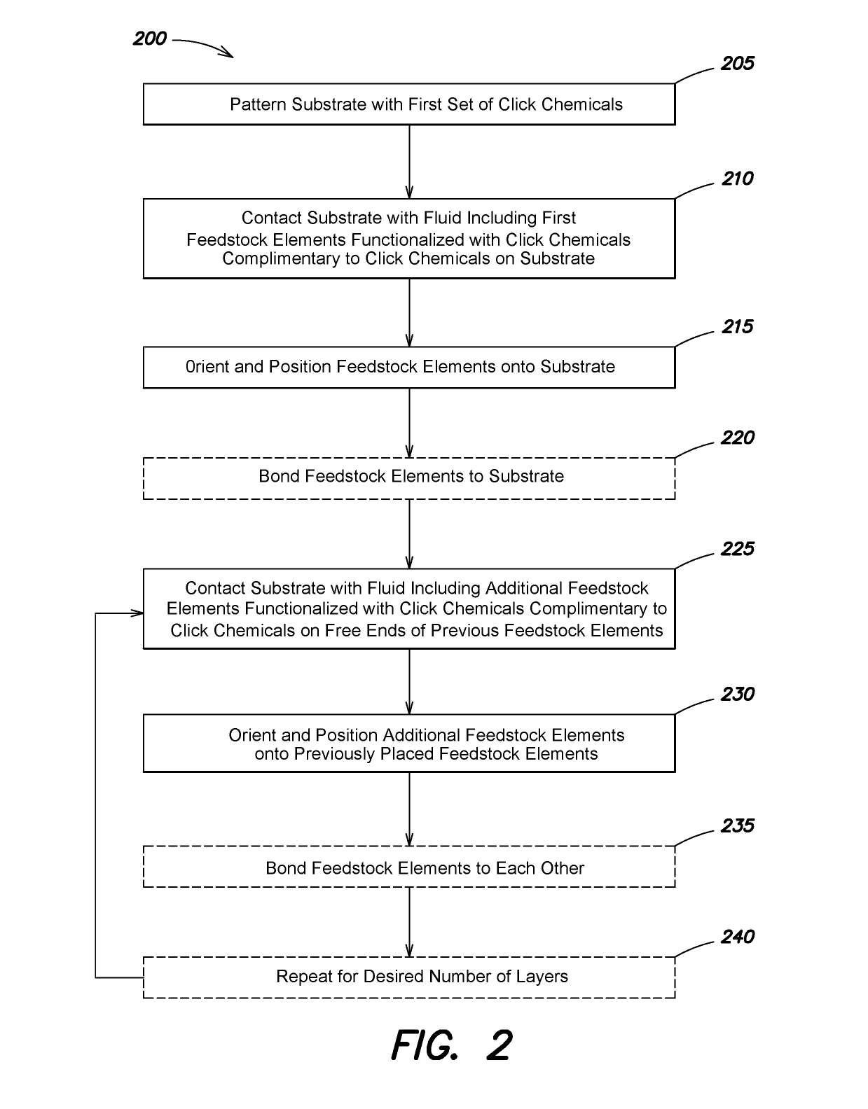

An embodiment of a DFA process 200 for fabricating an array of objects from two layers of micro-scale elements is shown schematically in FIGS. 1A-1E and is represented in the flowchart of FIG. 2. In act 205 of FIG. 2, represented in FIG. 1A, a substrate material 10, for example, a silicon wafer is patterned with a first set of functional moieties A, also referred to herein as “click chemicals.” The substrate 10 is patterned such that the functional moieties A are present in areas on the surface 15 of the substrate 10 where it is desired to connect micro-scale feedstock elements to the substrate 10. For example, the substrate 10 may be patterned with gold (Au) via electron-beam lithography and liftoff, or other patterning methods known in the art. A bifunctional molecule with one end being a thiol and the other end being an azide (the A side of the click reaction) may be placed in solution with the substrate. The thiol would then bind to the patterned gold surface, leaving the azide exposed for subsequent assembly to an alkyne (the A′ side of the click reaction)-functionalized feedstock in a subsequent step.

In act 210 of FIG. 2, represented in FIG. 1B, the patterned substrate 10 is placed in a fluid 20, for example, water, a buffer solution, an ionic liquid, or an organic solvent, containing micro-scale feedstock elements L1 that are functionalized with a click chemical A′ complimentary to the click chemical A present on the surface 15 of the substrate 10. For example, the micro-scale feedstock elements L1 may be in the form of micro-scale rods or cylinders having click chemical A′ present at one or both ends of the rods or cylinders. In one example, the feedstock elements L1 (or elements L2 or L3, referenced below) are fabricated laying on a surface (e.g., a silicon wafer) lined up in a two-dimensional array. The wafer may be placed in an electron-beam evaporator at a steep angle to the directional evaporation source such that one end of all the feedstock elements is exposed to the evaporated metal (e.g., gold) and a thin film of the metal is deposited only on those ends. The wafer is then turned 180 degrees and a metal (possibly gold, possibly another metal or dielectric) is deposited on the other end faces. The feedstock elements are then released from the substrate by etching away the underlying layer. The feedstock elements are placed in solution with a bifunctional molecule with one end being a thiol and the other end being an alkyne (the A′ side of the click reaction). The thiol will bind to the gold, leaving the alkyne exposed for subsequent assembly to an azide on a next feedstock element.

FIG. 1B illustrates a homogeneous population of micro-scale feedstock elements L1, however, in other embodiments, the fluid 20 may include a heterogeneous population of micro-scale feedstock elements of different sizes and/or shapes. In some embodiments, different click chemicals may be patterned on different areas of the substrate 10. Differently sized and/or shaped micro-scale feedstock elements in the fluid 20 may be provided with different click chemicals complimentary to the different click chemicals patterned on the substrate 10 so that the differently sized and/or shaped micro-scale feedstock elements may be bonded to different areas of the substrate 10 in a single process.

In act 215 of FIG. 2, represented in FIG. 1C, the micro-scale feedstock elements L1 are oriented and positioned on the surface 15 of the substrate 10. In different embodiments, any one or more of dielectrophoresis, electrophoresis, flow, convection, capillary forces, and magnetic fields, diffusion, or combinations thereof are used to orient and position the feedstock onto the substrate. Once the micro-scale feedstock elements L1 are in position, the click chemistry locks the micro-scale feedstock elements L1 in place by forming a covalent bond between click chemicals A and A′. In some embodiments, the covalent bond between click chemicals A and A′ is initiated by the addition of energy, for example, heat or ultraviolet light and/or a chemical initiator (act 220 of FIG. 2).

In act 225 of FIG. 2, represented in FIG. 1D, the substrate 10 having the micro-scale feedstock elements L1 bonded thereto is contacted with a second liquid 30 including a second layer of micro-scale feedstock elements L2. The free ends 25 of the micro-scale feedstock elements L1 are functionalized with another click chemical that is complimentary to a click chemical present on ends of the micro-scale feedstock elements L2. In some embodiments, the free ends 25 of the micro-scale feedstock elements L1 are functionalized with the same click chemical A′ that the ends bonded to the substrate included and the micro-scale feedstock elements L2 are functionalized with the click chemical A that was patterned on the surface 15 of the substrate. In other embodiments, different click chemical pairs B-B′ are used to bond the first and second layers of micro-scale feedstock elements L1, L2. In some embodiments, liquid 30 is the same liquid as liquid 25 and bonding of the micro-scale feedstock elements L1 to the substrate 10 may occur concurrently with bonding of the micro-scale feedstock elements L2 to the micro-scale feedstock elements L1. In some embodiments, different triggers, for example, different types or levels of energy or different chemical initiators are used to initiate bonding of the micro-scale feedstock elements L1 to the substrate 10 and bonding of the micro-scale feedstock elements L2 to the micro-scale feedstock elements L1.

In act 230 of FIG. 2, represented in FIG. 1E, the micro-scale feedstock elements L2 are oriented and positioned on the micro-scale feedstock elements L1, for example, in an end-to-end configuration. In different embodiments, any one or more of DEP, diffusion, and/or convection are used to orient and position the micro-scale feedstock elements L2 on the micro-scale feedstock elements L1. Once the micro-scale feedstock elements L2 are in position, the click chemistry locks the micro-scale feedstock elements L2 in place on the micro-scale feedstock elements L1 by forming a covalent bond between click chemicals A and A′. In some embodiments, the covalent bond between click chemicals A and A′ is initiated by the addition of energy, for example, heat or ultraviolet light and/or a chemical initiator (act 235 of FIG. 2).

In accordance with process 200, additional layers of feedstock material may be added to previously bonded micro-scale feedstock elements until a desired number of layers is reached to form a desired macro-scale object (act 240 of FIG. 2). For example, a structure 40 including a substrate 10 and three layers of micro-scale feedstock elements L1, L2, and L3, is illustrated in FIG. 1F. In some embodiments, the one or more of the micro-scale feedstock elements L1, L2, and L3, or additional micro-scale feedstock elements connected directly or indirectly to elements L3, may be connected substantially perpendicular to the substrate 10 or at an angle of between zero degrees and about 45 degrees relative to the substrate. In some embodiments, the one or more of the micro-scale feedstock elements L1, L2, and L3, or additional micro-scale feedstock elements connected directly or indirectly to elements L3, may be connected substantially co-linearly to one or more other of the feedstock elements or at an angle of between zero degrees and about 45 degrees relative to one or more other of the feedstock elements. In some embodiments, the micro-scale feedstock elements L1 may be rods or cylinders having dimensions of about 100 micrometers (μm) by about 5 μm, micro-scale feedstock elements L2 may be rods or cylinders having dimensions of about 10 μm by about 0.5 μm, and micro-scale feedstock elements L3 may be rods or cylinders having dimensions of about 1 μm by about 0.1 μm. These dimensions are examples only and do not limit the present disclosure. Method 200 is not limited to only 3 layers of micro-scale feedstock elements; any number of layers of similarly or differently shaped and sized micro-scale feedstock elements may be connected to form a macro-structure as disclosed herein. In some embodiments micro-scale feedstock elements comprising or consisting of single or multi-walled carbon nanotubes or nanorods or nanoparticles of metals, polymers, or dielectrics, having lengths and/or widths of less than a micron may be utilized.

By patterning the substrate and faces or ends of the feedstock with click chemicals, 2-D and 3-D structures may be created. By patterning click chemicals on specific locations on the faces or ends of the feedstock, different layers of feedstock elements may be oriented at any desired orientation relative to each other. DFA is a rapid and scalable manufacturing technique due to its parallel nature. However, compared to some slower pick-and-place manufacturing techniques, DFA may suffer from defects, and thus may be best suited for defect-tolerant applications. For less defect tolerant structures, DFA could be combined with error-checking and/or pick-and-place correction techniques to achieve low defect levels at high fabrication rates.

### Fabrication of Micro-Scale Elements

Micro-scale feedstock elements utilized in forming 2-D and 3-D structures disclosed herein may be formed from materials including, for example, silicon, silicon dioxide, silicon nitride, silicon carbide, SU-8 photoresist or other organic or inorganic polymers, biologically-based materials, for example chitosan, or other materials selected based on, for example, desired mechanical, thermal, optical, electrical, magnetic, and/or chemical properties.

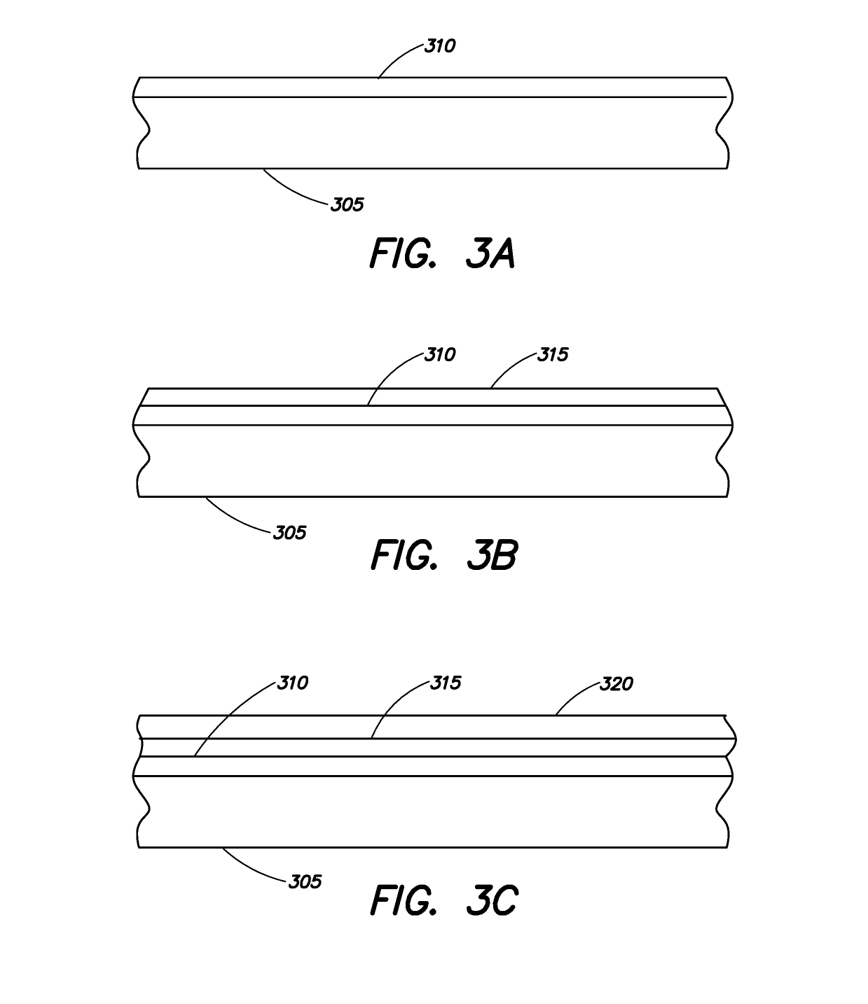

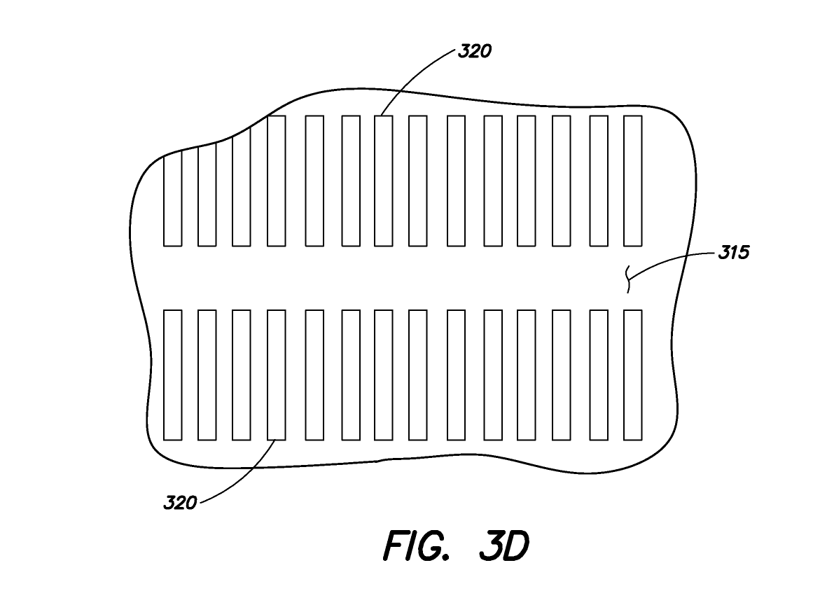

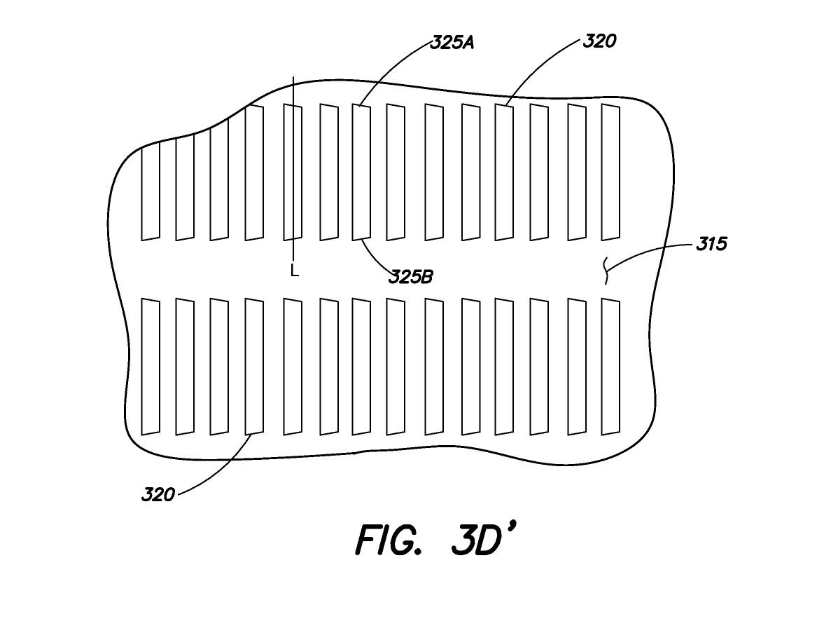

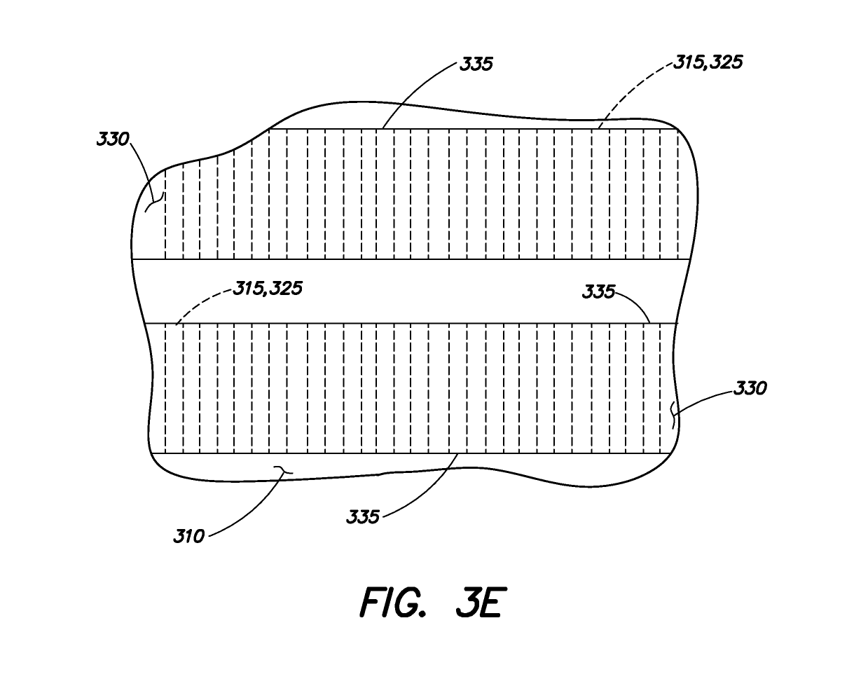

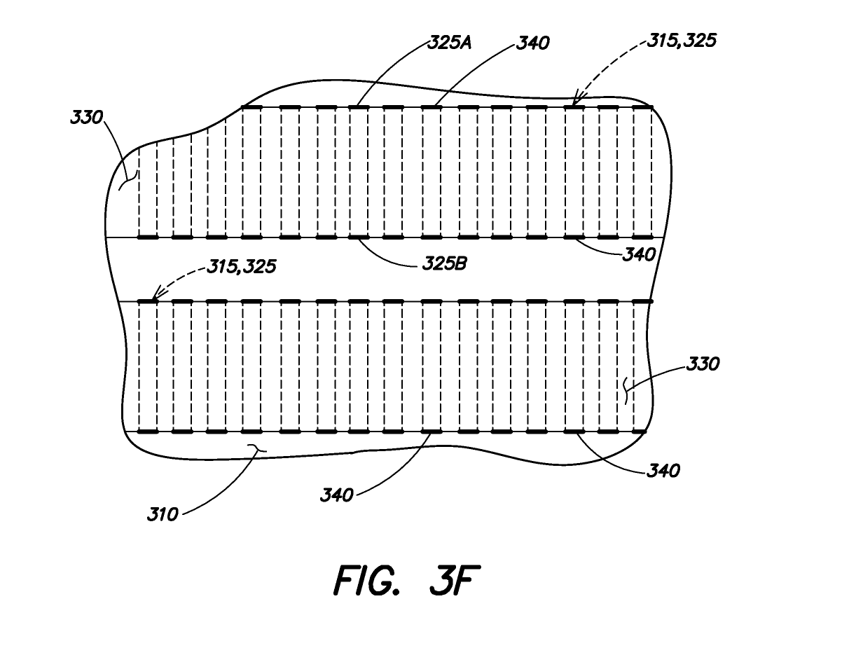

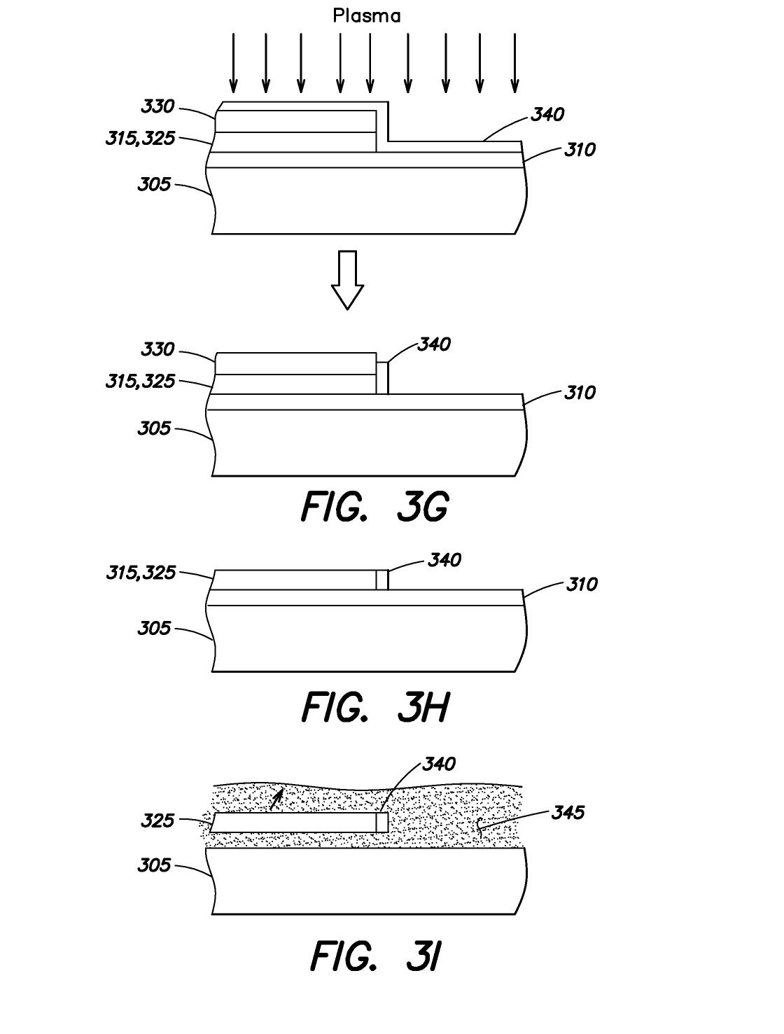

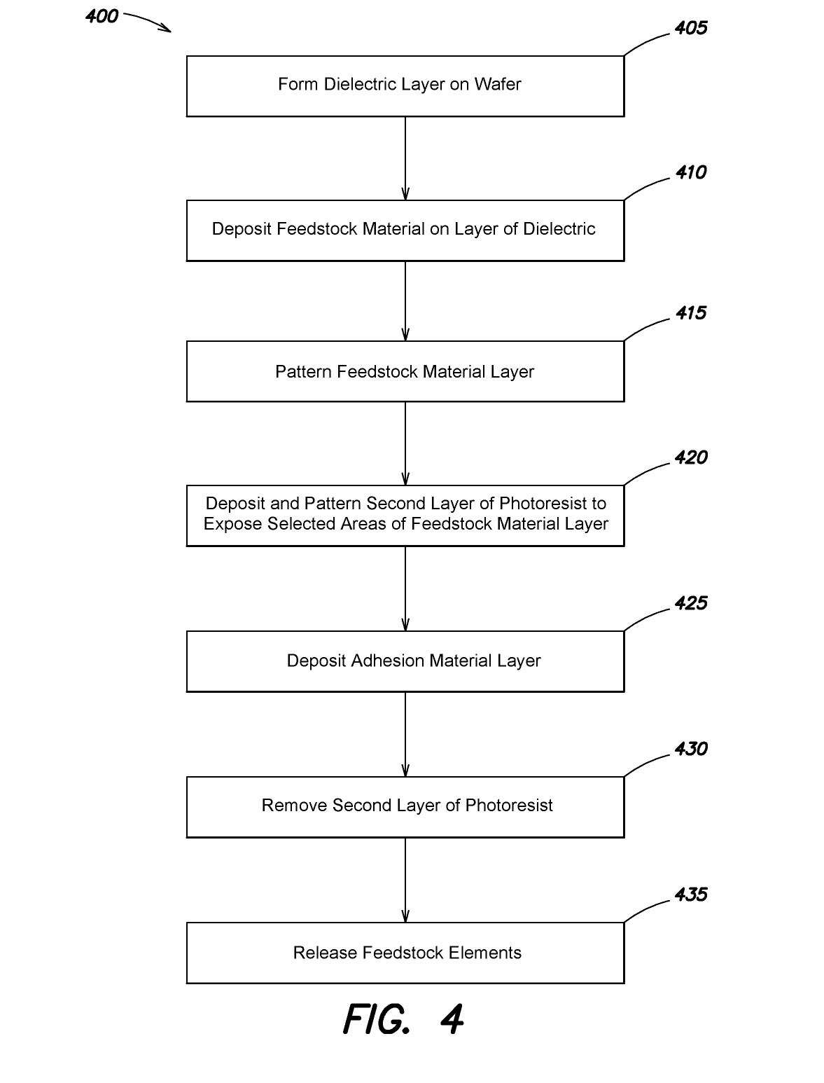

Micro-scale feedstock elements utilized in forming 2-D and 3-D structures disclosed herein may be formed using processes similar to those used in the fabrication of electronic devices in the semiconductor industry and/or micro electro mechanical system (MEMS) devices. One example of a method 400 for forming micro-scale feedstock elements utilized in forming 2-D and 3-D structures disclosed herein is described in the flowchart of FIG. 4 and the schematic diagrams in FIGS. 3A-3I.

In act 405, a substrate, for example, a silicon wafer 305 (or alternatively, sapphire, a glass wafer, a piezoelectric material, quartz or another insulator, or another substrate material desired for a particular implementation) is provided and a sacrificial layer of dielectric 310 for example, silicon dioxide (SiO₂) or silicon nitride (Si₃N₄ (which may be utilized when forming a feedstock element from SiO₂)) is grown on the face of the silicon wafer 305 using a chemical vapor deposition (CVD) or diffusion process in a diffusion furnace as known in the semiconductor fabrication arts (See FIG. 3A, illustrating a portion of the wafer 305 and layer of dielectric 310, not drawn to scale). The layer of dielectric 310 may be between about 100 nm and about 50 μm thick, although this range is an example only and is not intended to be limiting. As discussed below, in some embodiments a sacrificial polymer layer, for example, photoresist or polyvinyl alcohol (PVA) may be used in place of the dielectric 310.

In act 410 (FIG. 3B), a layer 315 of the desired feedstock material is then deposited on the layer of dielectric 310. The method of deposition is dependent on the type of feedstock material. For example, if the feedstock material is Si, SiO₂, or Si₃N₄, the feedstock material may be deposited via a CVD process, a spin-on glass process, or grown in a diffusion furnace. If the feedstock material is a metal it may be deposited using an electroplating process or a physical vapor deposition process such as sputtering or evaporative deposition. Photoresists or other polymers may be deposited on the layer of dielectric 310 using a spin-on process, optionally followed by a bake process to remove volatile solvents from the photoresist or other polymer. These and other processes for depositing various materials on a layer of dielectric 310 on a wafer are well known in the semiconductor fabrication arts and will not be described in detail herein. The layer 315 of feedstock material may be between about 0.1 μm and about 100 μm thick, although this range is an example only and is not intended to be limiting.

In act 415, the layer 315 of the feedstock material is patterned. Patterning of the layer 315 of the feedstock material may be accomplished using known methods of patterning of features on a semiconductor wafer. For example, a layer of photoresist 320 may be deposited conformally over the layer 315 of the feedstock material by spin coating and prebaked to drive off excess photoresist solvent. (FIG. 3C.) The layer of photoresist 320 is then exposed to crosslinking radiation (for negative photoresist), for example, ultraviolet light, through a photomask to define patterns in the crosslinked layer of photoresist 320 having dimensions desired for the micro-scale feedstock elements and optionally subjected to a post-exposure bake to help reduce standing wave phenomena caused by the destructive and constructive interference patterns of the crosslinking radiation. The non-crosslinked photoresist is then removed in a developing process by exposure to a developer chemical, for example, a developer such as tetramethylammonium hydroxide, and optionally subjected to a hard bake to solidify the remaining photoresist. The removal of the non-crosslinked photoresist exposes portions of the layer 315 of the feedstock material (FIG. 3D, illustrating an enlarged plan view of a portion of the wafer, aspect ratios of portions of layer 315 covered by remaining photoresist 320 not shown to scale) which is then etched using dry and/or wet etch processes depending on the type of feedstock material to form the micro-scale feedstock elements 325 from the layer 315 with the desired dimensions. The remaining crosslinked photoresist 320 is them removed by chemical resist stripping and/or by thermal decomposition in an ashing process and the wafer 305 may be cleaned, for example, in a sulfuric acid/hydrogen peroxide solution as is known in the semiconductor fabrication arts. In some embodiments, for example, as illustrated in FIG. 3D′ (also shown in feedstock elements L1 in FIG. 1F), one or both ends 325A, 325B of the micro-scale feedstock elements 325 may be patterned at an angle relative to a lengthwise axis L of the feedstock elements 325 (for example, between 0 and about 45 degrees) to facilitate attaching the feedstock elements 325 to a substrate or to other feedstock elements at an angle.

In act 420 a second layer of photoresist 330 is then deposited on the micro-scale feedstock elements 325 and patterned such that only portions of the feedstock elements 325 that are desired to be functionalized are exposed. (FIG. 3E.) In some embodiments, after patterning of the second layer of photoresist 330, end portions of the feedstock elements 325 that are exposed are etched away so only end surfaces 335 of the micro-scale feedstock elements 325 are exposed.

In act 425 an adhesion material 340 to which a click chemical group and associated binder molecule is later to be bonded is deposited on the exposed portions of the feedstock elements 325. (FIG. 3F.) In some embodiments, the binder molecule will attach directly to the exposed feedstock while the rest of the feedstock is protected under the photoresist. In some embodiments, material 340 includes or consists of a metal or semiconductor, for example, gold, silicon, iron or iron oxides, nickel, or an organic polymer. In some embodiments, the material 340 is conformally deposited by CVD or an evaporation deposition process. In other embodiments, where the exposed portions of the feedstock elements 325 are exposed at their upper surfaces, or if the wafer 305 can be oriented in a deposition chamber of a sputtering tool to expose the exposed portions of the micro-scale feedstock elements 325 in a direction toward a sputtering material target, a sputtering process may be utilized to deposit the material 340. The second layer of photoresist 330 is then removed, for example, by wet chemical etching which will also remove the material sputtered onto the photoresist, leaving the ends of the rods coated in the sputtered material. In some embodiments, act 425 is repeated to deposit different materials 340 on different portions of the micro-scale feedstock elements 325, for example, different materials at different ends 325A, 325B of the feedstock elements 325. In some embodiments, as illustrated in FIG. 3F, the material 340 selectively deposits on exposed portions of the feedstock elements 325. In alternate embodiments, a masking material is used instead of adhesion material 340 to define areas of the micro-scale feedstock elements 325 to which a click chemical group and associated binder molecule is later to be prevented from bonding to.

In other embodiments, the material 340 deposits conformally over the second layer of photoresist 330, the exposed portions of the feedstock elements 325, and the exposed surface of dielectric layer 310, in which instance a further photoresist layer may be deposited to cover the portions of the feedstock elements 325 onto which the material 340 was deposited and expose the surface of dielectric layer 310 on which the material 340 was deposited so that the material 340 may be etched off of the surface of dielectric layer 310 on which the material 340 was deposited, for example, with a wet etch. The further layer of photoresist would then be removed. Alternatively or additionally, material 340 deposited on the exposed surface of dielectric layer 310 may be removed with an anisotropic dry etch (for example, an argon plasma etch) with or without providing a layer of photoresist to protect the ends of the feedstock elements 325 onto which the material 340 was deposited. (See FIG. 3G, a schematic cross sectional illustration through a portion of one of the feedstock elements and adjacent structures.)

In act 430, the second layer of photoresist 330 is removed, for example, by thermal decomposition and/or chemical dissolution. Portions of the material 340 adhered to the second layer of photoresist 330 may also be removed in this act, resulting in the feedstock element layer 315 including the material 340 attached to the feedstock elements remaining on the layer of dielectric 310. (FIG. 3H.)

In act 435, the micro-scale feedstock elements 325 are released from the wafer 305 by dissolving or etching away the dielectric layer 310 by exposure to a wet etching agent 345, for example, hydrofluoric acid if the dielectric layer 310 is SiO₂, phosphoric acid if the dielectric layer 310 is Si₃N₄, or other suitable etching agents selected depending on the material of the dielectric layer 310. In act 435 the released micro-scale feedstock elements 325 are collected, for example, by filtering the etching agent 345 used to release them and optionally washed to neutralize the etching agent.

Various modifications may be made to the above process. For example, instead of a layer of dielectric 310 being deposited on the silicon wafer 305 and then removed by chemical etching, a layer of a polymer, for example, a photoresist, polyimide, or another polymer, may be deposited on the silicon wafer 305 and later removed by, for example, exposure to a solvent (ethylene glycol, gamma-butyrolactone, cyclopentanone, N-Methyl-2-pyrrolidone, or other known solvents) and/or by thermal decomposition as is known in the semiconductor fabrication arts to release the formed micro-scale feedstock elements. Alternatively, polyvinylalcohol (PVA), which is soluble in water, could be used as layer 310 and subsequently removed by exposure to water in act 435. The photoresist 320 may be positive photoresist that becomes soluble when exposed to radiation through the photomask and thus is exposed in areas other than those having the desired shapes for the micro-scale feedstock elements 325. In some embodiments, the layer 315 from which the feedstock elements 325 are formed may itself be a photoimagable polymer, for example, SU-8, in which instance the first photoresist layer 220 may not be necessary and the layer 315 may be directly patterned by exposure to patterning radiation and development in developer solution. In some embodiments, differently sized and/or shaped micro-scale feedstock elements may be formed concurrently on the same wafer while in other embodiments only micro-scale feedstock elements having same dimensions are formed on a single wafer.

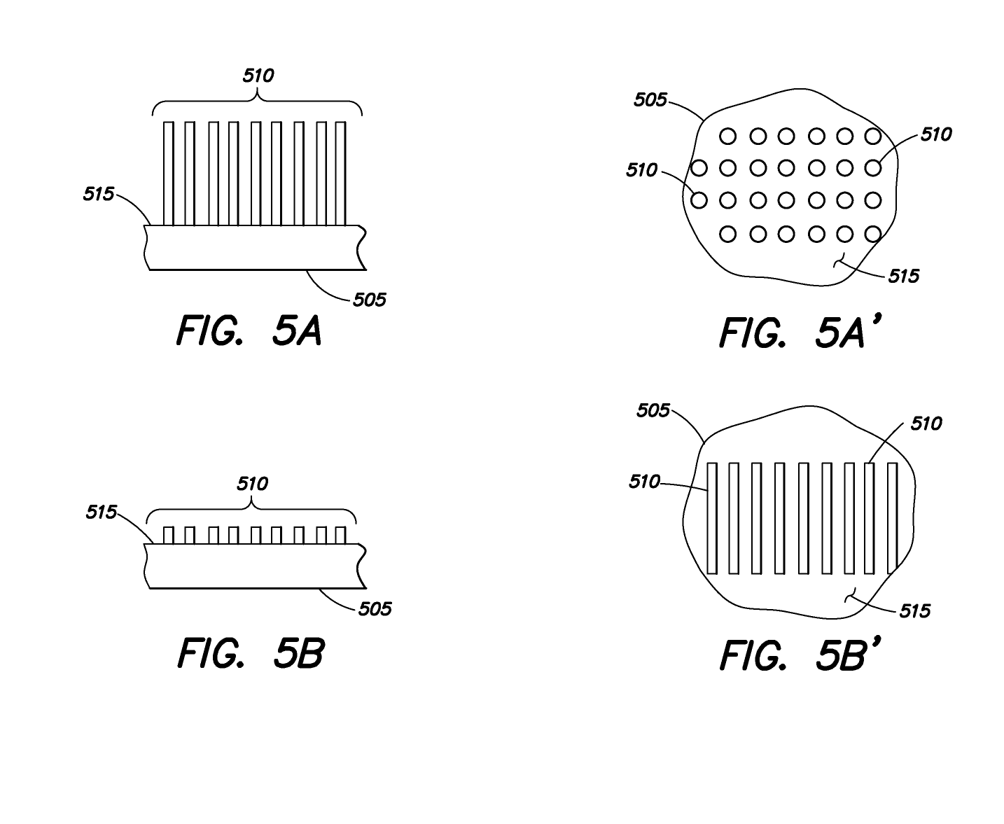

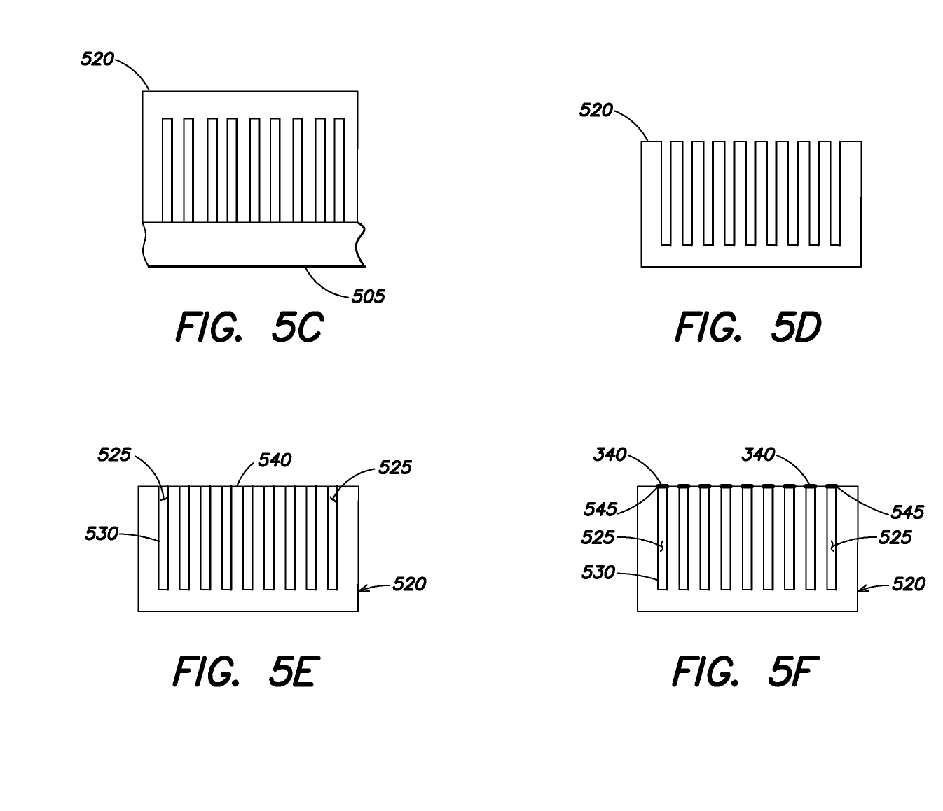

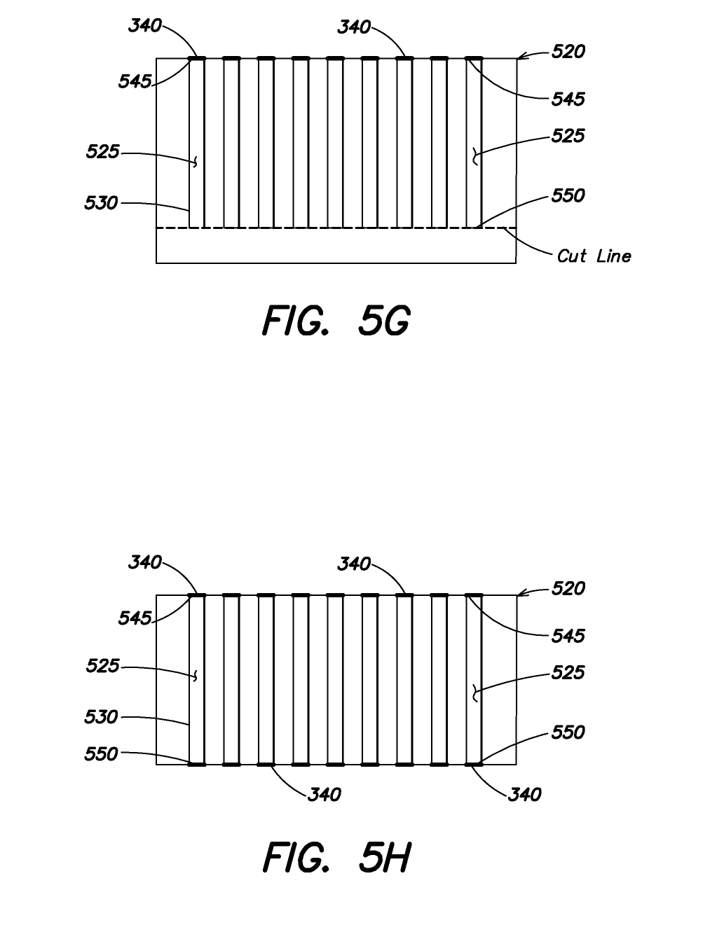

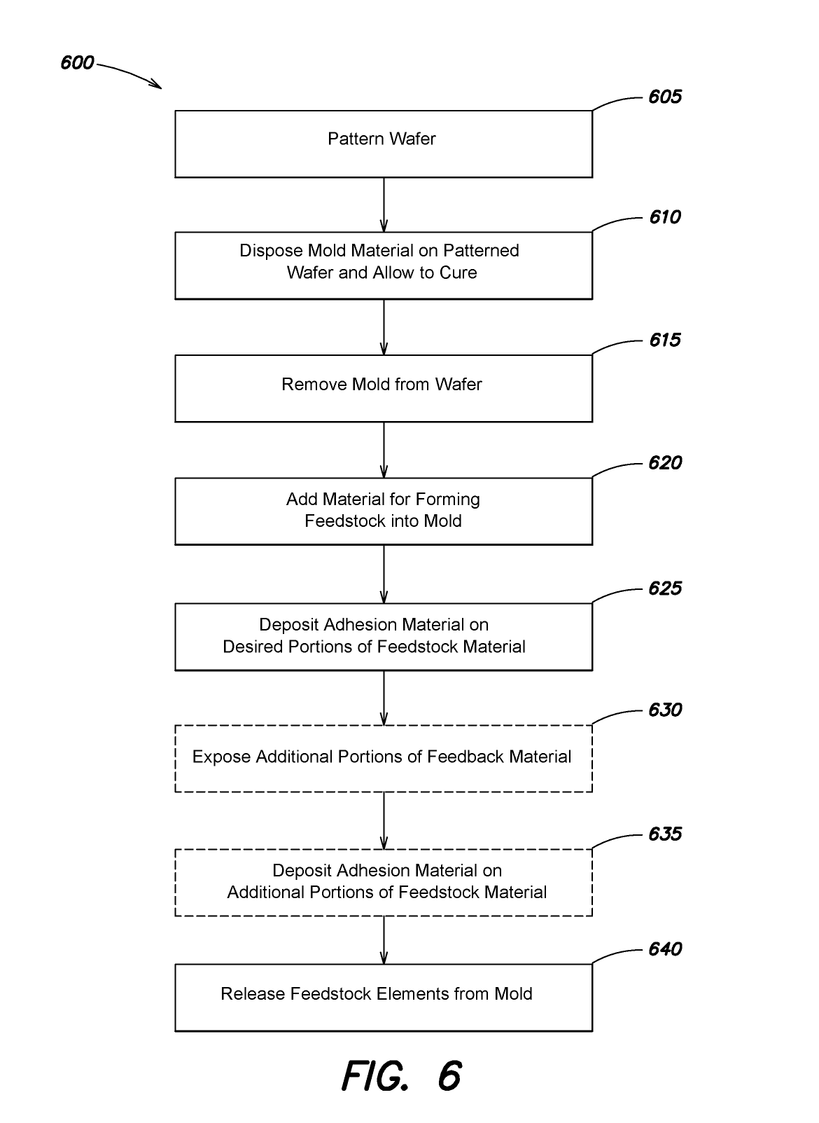

Another embodiment of a process 600 for forming micro-scale feedstock elements 325 is described with reference to FIGS. 5A-5E and the flowchart of FIG. 6. In act 605 a material, for example a semiconductor wafer 505 is patterned to exhibit an array of structures 510 having dimensions substantially similar to a desired micro-scale feedstock element 325 to be formed. In some embodiments, as illustrated in FIGS. 5A and 5A′, the structures may be oriented perpendicular to the surface 515 of the semiconductor wafer 505. In other embodiments, as illustrated in FIGS. 5B and 5B′, the structures may be oriented parallel to and disposed on the surface 515 of the semiconductor wafer 505. The structures 510 may be substantially cylindrical, substantially rectangular in cross-section or any other shape and with dimensions desired for the micro-scale feedstock elements 325.

In act 610, a mold material, for example, wax, silicone, an epoxy-based material, or another mold materials known in the art is deposited on the array of structures and allowed to cure to form a mold 520. (FIG. 5C.) In some embodiments, a release agent is deposited on the array of structures prior to deposition of the mold material. Examples of release agents include, for example, vapor-deposited polytetrafluoroethylene, or vapor-deposited dimethyldichlorosilane available as PlusOne Repel-Silane ES from GE Healthcare Life Sciences

In act 615, the cured mold 520 is removed from the semiconductor wafer 505 and array of structures 510. (FIG. 5D.)

In act 620 a desired material 525, in a liquid or slurry form, is deposited in the impressions 530 in the mold 520 formed by the array of structures 510 and excess material 525, for example, from the surface 540 of the mold is removed. (FIG. 5E.) The material 525 is allowed to solidify or cure. Heat and/or radiation, for example, UV light, actinic radiation, or other forms of radiation, may be applied to the material 525 to facilitate and/or accelerate solidification or curing.

In act 625 a layer of adhesion material 340, for example, any one or more of the adhesion materials 340 discussed above is deposited on desired portions of the solidified material 525, for example, on end portions 545 exposed in the impressions 530 in the mold 520. (FIG. 5F.) In some embodiments, the one or more of the adhesion materials 340 are deposited by a physical deposition method, for example sputtering or evaporative deposition. In other embodiments, the one or more of the adhesion materials 340 are deposited by a screen printing or other deposition method.

In some embodiments where it is desired to deposit the one or more of the adhesion materials 340 on additional portions of the solidified material 525, the mold 520 may be cut to expose the additional portions, for example, other end portions 550 of the solidified material 525. (FIG. 5G, optional act 630.) The one or more of the adhesion materials 340 may then be deposited on the additional portions using a similar method as the or more of the adhesion materials 340 was deposited on the first desired portions. (FIG. 5H, optional act 635.)

In act 640, the solidified material 525 with the deposited adhesion material(s) 340 is removed from the mold 520, for example by melting of the mold material, dissolution of the material of the mold in a solvent, by cutting the solidified material 525 from the mold, or by other methods known in the art, resulting in a plurality of free micro-scale feedstock elements 325 which are then collected for later use.

In some embodiments disclosed herein, structures are formed including carbon nanotubes as micro-scale feedstock elements. Carbon nanotubes may have diameters as small as a few nanometers. Carbon nanotubes may be formed by a CVD process in which the carbon nanotubes form on metal catalyst particles, for example, particles of nickel, cobalt, iron, or a combination thereof. The catalyst particles can stay at the tips of the growing nanotube during growth, or remain at the nanotube base during growth. The catalyst particles are often removed from carbon nanotubes available from various suppliers. However, in some embodiments the catalyst particles may be retained on the carbon nanotubes and used as the adhesion material 340 to which click chemicals and associated binder molecules may be adhered to facilitate attachment of the carbon nanotubes to other micro-scale feedstock elements.

### “Click” Chemistry

“Click chemistry” is a term for a type of chemical synthesis used for generating substances quickly and reliably by joining small units together. Click chemistry describes a way of generating products that follows examples in nature, which also generates substances by joining small modular units. The term was coined by K. Barry Sharpless in 1998, and was first fully described by Sharpless, Hartmuth Kolb, and M. G. Finn of The Scripps Research Institute in 2001.

In some embodiments, “click chemistry” reactions are used to join micro-scale feedstock elements to substrates and/or other micro-scale feedstock elements to form embodiments of structures disclosed herein. Feedstock faces to be joined (and/or feedstock faces and areas of a substrate to be joined) are patterned with complementary chemical groups, referred to herein as A-A′ pairs, that will bond them together with covalent, permanent click reactions. Such covalent bonds are stable to variations in solution conditions, temperature, and removal of water, making them a highly robust approach to hierarchical structure assembly.

Various different “click” reactions may be utilized in embodiments of assembly methods and structures disclosed herein. In one example, alkyne (or cyclooctyne) and azide functional groups represent one such A-A′ pair, displaying one of the most efficient, selective and versatile click reactions known, Huisgen 1,3-dipolar cycloaddition. In another example, the Michael addition of thiols to alkenes (i.e. maleimides) may be used as an alternate A-A′ pair. The reaction of aldehydes with alkoxyamines to form oximes provides a third A-A′ pair that is orthogonally reactive. Further, the oxidative coupling of substituted phenols to anisidine derivatives may be used to provide a fourth A-A′ coupling.

The high reactivity of the click-active functional moieties is incompatible with most traditional lithographic patterning schemes. To overcome this limitation, some embodiments involve conventional microfabrication techniques to bond an intermediate material to portions of a substrate or a micro-scale feedstock element that is used to bond a click chemical group and/or a linker molecule and click chemical group to the substrate or a micro-scale feedstock element. In some embodiments, a surface of a substrate is patterned with a material to which precursors that will bind to the click chemistries will selectively functionalize (e.g. gold surfaces to which thiols will bind, silicon surfaces to which silanes will bind, or iron oxides and other metals to which carboxyl groups will bind). If micro-scale feedstock elements are fabricated in a template or mold as discussed above (for example, as electroplated pillars in a mold) functionalization could occur on the exposed faces before removal from the mold.

In other embodiments, the dual functions of ‘clickability’ and direct e-beam ‘patternability’ down to about 110 nm resolution may be achieved by the rapid, one-step, synthetic process of initiated Chemical Vapor Deposition (iCVD). In one embodiment, an iCVD poly(propargyl methacrylate) (PPMA) surface displays alkyne functional groups and may be directly patterning by e-beam exposure, obviating the need for a traditional photoresist layer to be deposited and patterned. The surface grafting possible by iCVD achieves the chemical and mechanical stability required for high resolution patterning. Grafting can be accomplished either by abstraction of an atom from the surface to directly create a reactive site or by reaction of a surface function group with a linker molecule. Ultrathin, adherent, and conformal iCVD polymers displaying dozens of different organic functional groups have been demonstrated and the library of iCVD, if needed, can be further expanded to meet the requirements of the click chemistry reaction schemes and pattern generation.

The iCVD functionalization method may be utilized for fabrication of dual functional patterned surfaces in which surface regions of click-active alkyne groups, A, are separated by regions displaying surface amine groups. The amine groups may be functionalized by carbodiimide chemistry with N-hydroxysuccinimide, N. Both the click reaction and amine functionalization are well-understood and possess high selectivity, high yield, and fast reaction rates in aqueous phase at room temperature. Moreover, the click and NHS reactions are highly orthogonal to each other to minimize nonspecific immobilization. When exposed to a mixture of dyes, the surface region functionalized by A, attaches only the dye with the conjugate functional group (A-A′). Likewise, only N—N′ coupling occurs on the other regions, resulting in the dyes being sorted according to the predesigned pattern on the surface. By using functionalized feedstock in place of dyes, this technique can be used for linking patterned assembled feedstock.

The all-dry nature of the iCVD process is an advantage in designing multi-step fabrication schemes. Considering ease of fabrication and the versatility and orthogonality of the reactive functional groups utilized, and generality of the thin film deposition method, prove for the iCVD platform to be extended to self-sorted assembly of substrates and feedstock possessing the appropriate conjugate functionalities. The conformal nature of iCVD makes it amenable to coating the entire surface of substrates and/or feedstock. Combining iCVD with templates or molds to cast feedstock elements allows the selective coating of one or more surfaces of feedstock elements while leaving its other surfaces uncoated.

After microfabrication of building blocks and functionalization with chemically distinct surfaces, the relevant “click” precursor groups are grafted to the surface of substrates and/or feedstock to produce surfaces with the desired functionality. The specificity of click reactions will potentially enable multiple reactions to be performed simultaneously, providing maximum versatility in the design of the assembly final particle assembly process. In some embodiments, all “click” reactions may be performed under conditions where they are spontaneous, such that when two surfaces come into contact they react instantly to form a strong, permanent bond. In other embodiments, for example, if the fast rate of reaction leads to an unacceptable level of defects, the reactions may be performed under activated conditions, where the addition of a catalyst (Cu for azide-alkyne, a thiol reductant for thiol-maleimide, aniline for oxime chemistry, or the oxidant for phenol oxidative coupling) is used to trigger the covalent bond only once the particles have annealed into the correct configuration. In this case, weak non-covalent interactions such as hydrogen bonding donors/acceptors or electrostatic interactions can be used to promote appropriate orientation of feedstock on a substrate or other feedstock before covalent bond formation.

In some embodiments, a linker may be used to join the click chemical groups to metal patterns on a substrate and/or to feedstock elements. The linker may be considered a spacer between the surface functionalization (i.e. thiol) and the click chemistry. Examples of linkers include alkyls, aryls, or heteroatom substituted alkyl chains (which allow tunability of solubility, spacing, and/or mechanical stiffness.

In some embodiments, to facilitate joining surfaces on substrates and/or feedstock elements that are not fully planar, surfaces to be joined may be provided with a thin layer of a compliant material, for example, an i-CVD-deposited polymer that is less stiff than the underlying substrate and/or feedstock material or with a longer, softer linker molecule such as heteroatom substituted alkyl chains.

### DNA Selective Assembly

In the field of medical diagnostics, DNA selective sensors have been developed that allow for one to detect the presence of one or more pathogens (for example, virus or bacteria) in a fluid sample by sensing the presence of strands of DNA specific to the one or more pathogens. Various DNA selective sensors include a sensor element, for example, a thin gold wire or other nanostructure to which a portion of a strand of DNA complimentary to the DNA of a pathogen of interest has been attached. When a strand of DNA of the pathogen having an order of base units (A, C, G, T) complimentary to the strand of DNA attached to the sensor element contacts the strand of DNA attached to the sensor element, the two strands of DNA bond together and produce a mechanical or electrical change on the sensor element that may be detected to provide an indication of the presence of the pathogen.

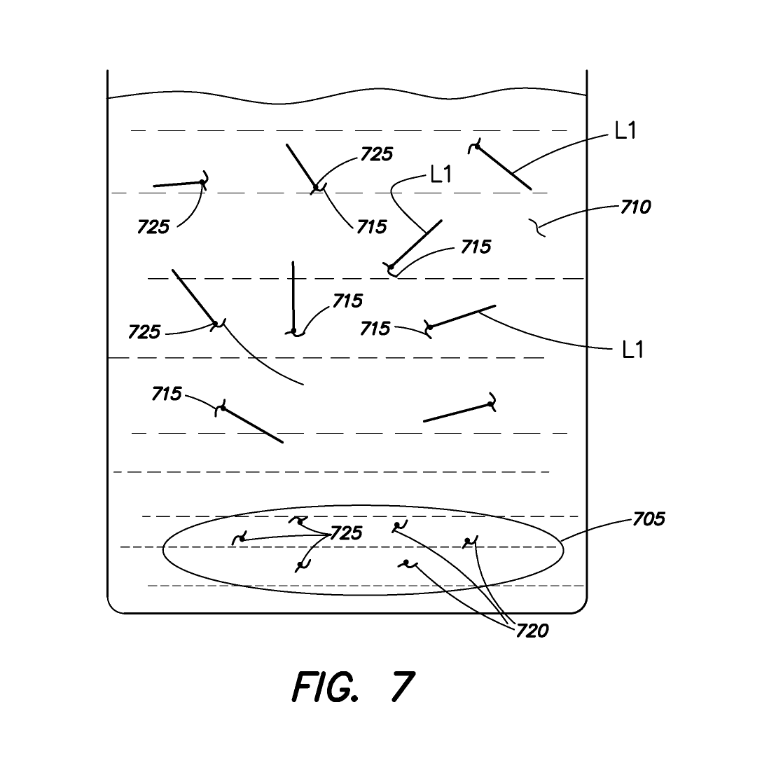

In some embodiments, the ability of complimentary strands of DNA to selectively bond to one another may be capitalized on to provide for a method of joining micro-scale feedstock elements as disclosed herein. For example, in some embodiments, a first strand of DNA is bonded to a substrate in locations where it is desired to attach first micro-scale feedstock elements. A strand of DNA complimentary to the first strand of DNA is bonded to an area of a first micro-scale feedstock elements desired to be bonded to the substrate. As illustrated in FIG. 7, the first micro-scale feedstock elements L1 are placed in a solution 710 and the substrate 705 is exposed to the solution 710. The first micro-scale feedstock elements L1 are then aligned with and positioned on the substrate 705 via a DFA process, for example, using dielectrophoresis as described above. When a strand of DNA 715 on one of the first micro-scale feedstock elements L1 comes into proximity with a complimentary strand of DNA 720 on the substrate 705, the two strands of DNA are drawn together, joining the first micro-scale feedstock element L1 to the substrate 705.

In some embodiments, in addition to providing for bonding of the first micro-scale feedstock element L1 to the substrate 705 with the complimentary DNA strands, additional bonding mechanisms 725 are provided. For example, in addition to the complementary DNA strands, one or both of the substrate 705 and the first micro-scale feedstock element L1 are provided with an additional bonding mechanism 725 at the desired bonding locations. The additional bonding mechanisms 725 may include, for example, but without limitation, an adhesive that may be activated by heat (wax, hot-melt adhesive, etc.) or exposure to one or more forms of radiation (UV light, actinic radiation, etc.) and/or a solder material (for example, an indium/gold or lead/tin eutectic alloy). After the first micro-scale feedstock element L1 is bonded to the substrate 705 via the complimentary DNA strands, the additional bonding mechanisms may be activated by application of heat or radiation to form a bond between the first micro-scale feedstock element L1 and the substrate 705 that may be stronger than the bond between the complimentary DNA strands and that may be more robust in dry environments than the bond between the complimentary DNA strands.

Additional micro-scale feedstock elements may be functionalized with DNA strands complimentary to other DNA strands bonded to desired areas on the first micro-scale feedstock element L1 to provide for the additional micro-scale feedstock elements to be bonded to the first micro-scale feedstock element L1 in a similar manner as the first micro-scale feedstock element L1 is bonded to the substrate 705. This DNA assisted bonding process may be extended to join a plurality of levels of micro-scale feedstock elements into a desired structure.

### Prophetic Example—Gecko Adhesive

DFA/click chemistry assembly processes as disclosed herein may be utilized to assemble large (wafer scale or larger) synthetic biomimetic gecko adhesive structures (setae).

The adhesive ability of gecko feet relies on van der Waals forces of a large number of ˜100 nm-diameter beta keratin nano-fibers or spatula extending from the surfaces of the feet. The gecko has an adhesive system that includes nanoscale spatulae along with hierarchical setal stalks, lamellae, branched digital tendons, blood-filled sinus cavities and toes at varying length scales from micrometers to centimeters and with a wide range of material properties. The gecko uses biological multiscale complexity to scale nanotechnology to the macroscale. No presently known synthetic adhesive system combines more than a few comparable features and none approaches the versatility of the gecko's adhesive system.

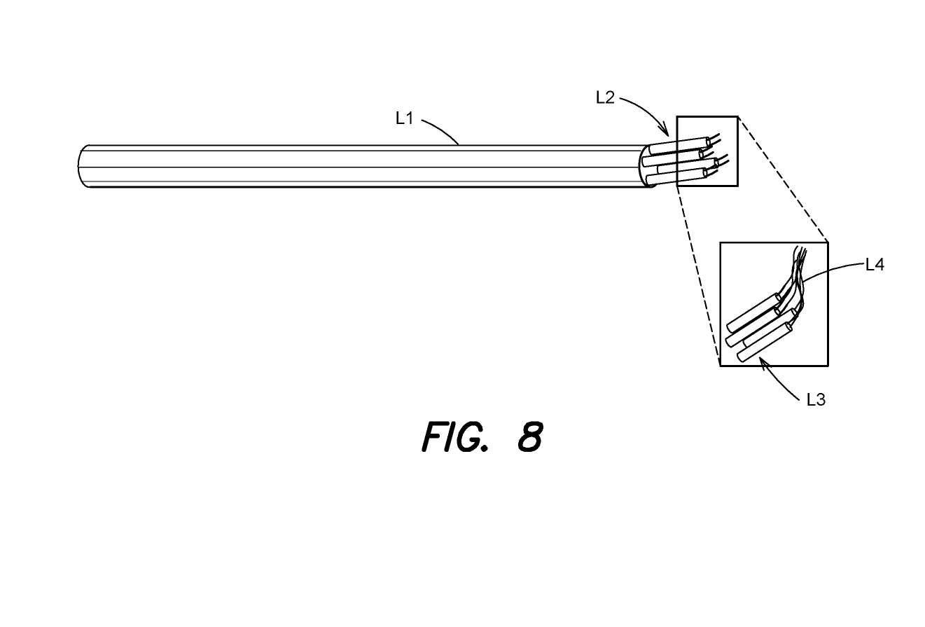

A synthetic gecko adhesive structure may be fabricated in accordance with the method described with reference to FIG. 2 above. Such a synthetic gecko adhesive will be an inexpensive, re-usable adhesive with applications in military, medical, and consumer products. The form of one synthetic gecko hair that may be formed in accordance with the methods disclosed herein is illustrated in FIG. 8. A substrate having a diameter of, for example, about 100 mm may be formed utilizing DFA/click chemistry processes as disclosed herein with up to 250 million or more synthetic gecko hairs formed with L1 micro-elements oriented substantially perpendicular to the surface of the substrate or at an angle between zero and about 45 degrees relative to a plane defined by the surface of the substrate. The microhairs of gecko feet are replicated by the L1 micro-element in FIG. 8, having dimensions of about 5 μm by about 100 μm, and an aspect ratio of at least about 20:1. Gecko nanohairs, which branch from gecko microhairs on natural gecko feet, are replicated by the L2 micro-elements in FIG. 8, having dimensions of about 0.5 μm by about 10 μm (an aspect ratio of at least about 20:1), the L3 micro-elements having dimensions of about 0.1 μm by about 1 μm (an aspect ratio of at least about 10:1), and the carbon nanotubes, having diameters of between about 1 nanometer and about 30 nanometers (an aspect ratio of at least about 10:1). To mimic the mechanical properties of natural gecko hair, comprising beta keratin, the L1, L2, and L3 micro-elements may be formed from, for example, SU-8 polymer or chitosan. The L1, L2, and L3 micro-elements may be formed using conventional micro/nanofabrication techniques such as used in the semiconductor industry as described above.

The synthetic gecko adhesive would be the most closely biomimetic gecko adhesive structure ever fabricated, since DFA allows higher aspect ratios and more size scale range then other fabrication approaches. As such, the disclosed synthetic gecko adhesive should more closely mimic the gecko, exhibiting significantly improved adhesion to rough, damp, and dirty surfaces, and better area adhesion scalability than other synthetic adhesives.

It is expected that the synthetic gecko adhesive may be tailored, for example, by selection of the lengths and diameters of the L3 micro-elements and/or carbon nanotubes, to exhibit surface adhesion strengths similar or greater than that of natural gecko feet. For example, it is expected that the synthetic gecko adhesive will be capable of withstanding up to or greater than about 0.09 N of force per mm² of adhesive substrate area applied parallel to a surface to which the synthetic gecko adhesive is adhered, up to or greater than about 200 μN of force per individual synthetic hair.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A method of assembly of micro-scale objects, the method comprising:
forming a pattern of a first functional moiety on a surface of a substrate;
contacting the surface of the substrate with a first liquid suspension including first micro-scale feedstock elements functionalized with a second functional moiety, complimentary to the first functional moiety, on first portions of the first micro-scale feedstock elements;
aligning the first portions of the first micro-scale feedstock elements in the first liquid suspension with the surface of the substrate; and
facilitating bonding the second functional moieties to the first functional moieties to form a first microstructure pattern of the first micro-scale feedstock elements on the surface of the substrate.

2. The method of claim 1, wherein second portions of the first micro-scale feedstock elements are functionalized with a third functional moiety, and the method further comprises:
contacting the first microstructure pattern of the first micro-scale feedstock elements on the surface of the substrate with a second liquid suspension including second micro-scale feedstock elements functionalized with a fourth functional moiety, complimentary to the third functional moiety, on first portions of the second micro-scale feedstock elements;
aligning the first portions of the second micro-scale feedstock elements in the second liquid suspension with the second portions of the first micro-scale feedstock elements; and
facilitating bonding the fourth functional moieties to the third functional moieties to form the assembly of micro-scale objects on the surface of the substrate.

3. The method of claim 2, further comprising:
contacting the assembly of micro-scale objects with a third liquid suspension including third micro-scale feedstock elements;
aligning and positioning first portions of the third micro-scale feedstock elements in the third liquid suspension with second portions of the second micro-scale feedstock elements; and
facilitating bonding the first portions of third micro-scale feedstock elements to the second portions of the second micro-scale feedstock elements with complimentary click chemical groups.

4. The method of claim 3, wherein aligning and positioning first portions of third micro-scale feedstock elements with second portions of the second micro-scale feedstock elements includes aligning and positioning first portions of third micro-scale feedstock elements with second portions of the second micro-scale feedstock elements with a dielectrophoretic field.

5. The method of claim 3, further comprising:
contacting the assembly of micro-scale objects with a fourth liquid suspension including one or more of carbon nanotubes, nanorods, and nanoparticles;
aligning and positioning first portions of the one or more of carbon nanotubes, nanorods, and nanoparticles in the fourth liquid suspension with second portions of the third micro-scale feedstock elements; and
bonding the one or more of carbon nanotubes, nanorods, and nanoparticles to the second portions of the third micro-scale feedstock elements with complimentary click chemical groups.

6. The method of claim 5, wherein aligning and positioning the first portions of the one or more of carbon nanotubes, nanorods, and nanoparticles with the second portions of the third micro-scale feedstock elements includes aligning and positioning the first portions of the one or more of carbon nanotubes, nanorods, and nanoparticles with the second portions of the third micro-scale feedstock elements with a dielectrophoretic field.

7. The method of claim 5, comprising concurrently bonding at least two of i) the first portions of the first micro-scale feedstock elements to the substrate, ii) the second portions of the first micro-scale feedstock elements to the first portions of the second micro-scale feedstock elements, iii) the first portions of the third micro-scale feedstock elements to the second portions of the second micro-scale feedstock elements, and iv) the one or more of carbon nanotubes, nanorods, and nanoparticles to the second portions of the third micro-scale feedstock elements.

8. The method of claim 5, comprising forming one of an electrical and an optical pathway to the substrate through one of the first micro-scale feedstock elements, the second micro-scale feedstock elements, the third micro-scale feedstock elements, and the one or more of carbon nanotubes, nanorods, and nanoparticles.

9. The method of claim 2, wherein the third functional moiety is the same as the first functional moiety.

10. The method of claim 9, wherein the fourth functional moiety is the same as the second functional moiety.

11. The method of claim 2, wherein the third functional moiety is the same as the second functional moiety.

12. The method of claim 11, wherein the fourth functional moiety is the same as the first functional moiety.

13. The method of claim 1, wherein facilitating bonding the second functional moieties to the first functional moieties includes initiating bonding between the second functional moieties and the first functional moieties by one of application of thermal energy to the second functional moieties and/or the first functional moieties, application of radiation to the second functional moieties and/or the first functional moieties, and exposing the second functional moieties and/or the first functional moieties to a chemical catalyst.

14. The method of claim 1, further comprising bonding the first functional moiety with a linker molecule to a metal adhesion element bonded to the surface of the substrate to form the pattern of the first functional moiety on the surface of the substrate.

15. The method of claim 1, further comprising bonding the second functional moiety with a linker molecule to a metal adhesion element bonded to the first portion of the first micro-scale feedstock element.

16. The method of claim 1, further comprising facilitating bonding a plurality of the second micro-scale feedstock elements to each of the second portions of the first micro-scale feedstock elements.

17. The method of claim 1, wherein facilitating bonding the second functional moieties to the first functional moieties includes facilitating bonding a first click chemical group to a complimentary click chemical group.

18. The method of claim 1, wherein facilitating bonding the second functional moieties to the first functional moieties includes facilitating bonding a first DNA strand to a complimentary DNA strand.

19. The method of claim 18, further comprising bonding the first micro-scale feedstock elements to the surface of the substrate with an additional bonding mechanism.

20. The method of claim 1, resulting in the formation of a synthetic gecko adhesive.

21. An assembly of micro-scale objects comprising:
a plurality of first micro-scale feedstock elements having first portions bonded to a surface of a substrate in a repeating pattern with click chemical bonds; and
a plurality of second micro-scale feedstock elements having first portions bonded to second portions of the plurality of first micro-scale feedstock elements.

22. The assembly of claim 21, wherein at least a portion of one of the first micro-scale feedstock elements and the second micro-scale feedstock elements have length:width aspect ratios of at least about 20:1.

23. The assembly of claim 21, further comprising a plurality of the second micro-scale feedstock elements bonded to each first micro-scale feedstock element.

24. The assembly of claim 21, further comprising a plurality of third micro-scale feedstock elements having first portions bonded to second portions of the plurality of second micro-scale feedstock elements with click chemical bonds.

25. The assembly of claim 24, further comprising a plurality of the third micro-scale feedstock elements bonded to each second micro-scale feedstock element.

26. The assembly of claim 25, further comprising a plurality of carbon nanotubes bonded to each of the third micro-scale feedstock elements.

27. The assembly of claim 24, wherein the first micro-scale feedstock elements have greater cross-sectional areas than each of the second micro-scale feedstock elements and the third micro-scale feedstock elements.

28. The assembly of claim 27, wherein the second micro-scale feedstock elements have greater cross-sectional areas than the third micro-scale feedstock elements

29. The assembly of claim 21, wherein the first micro-scale feedstock elements have cross-sectional areas of less than about 80 μm².

30. The assembly of claim 21, configured to adhere to a glass surface via van der Waals forces with an adhesion strength of at least about 0.09 N of force per mm².

31. The assembly of claim 21, comprising a synthetic gecko adhesive.
